(19) United States
(12) Patent Application Publication
(10) Pub. No.: US 2007/0105412 A1
(43) Pub. Date: May 10, 2007

(54) Electrical Connector For A Window Pane Of A Vehicle

(75) Inventors: Timothy P. Hoepfner, Grand Ledge, MI (US); Makoto Sato, Ann Arbor, MI (US)

Correspondence Address: HOWARD & HOWARD ATTORNEYS, P.C., THE PINEHURST OFFICE CENTER, SUITE #101, 39400 WOODWARD AVENUE, BLOOMFIELD HILLS, MI, 48304-5151, US

(73) Assignee: AGC AUTOMOTIVE AMERICAS R&D, INC., Ypsilanti, MI (US)

(21) Appl. No.: 11/619,081

(22) Filed: Jan. 2, 2007

Related U.S. Application Data
(63) Continuation-in-part of application No. 10/988,350, filed on Nov. 12, 2004.

(51) Int. Cl. H05K 1/00

(52) U.S. Cl. 439/83

(57) ABSTRACT

A window pane has a substrate formed from glass and includes an electrical device. The electrical device includes an electrical conductor and an electrical connector. A layer of solderable metal is bonded to the connector. A layer of solder is bonded to the layer of solderable metal and the conductor, with the connector and the conductor in electrical communication through the layer of solderable metal and the layer of solder. The substrate has a first coefficient of expansion and the connector has a second coefficient of thermal expansion. A difference between the first and second coefficients of thermal expansion is equal to or less than 5×10⁻⁶/° C. for minimizing mechanical stress between the connector and the substrate due to thermal expansion of the connector and the substrate resulting from changes in temperature. The solder is comprised of less than 70 parts by weight of Sn along with a greater than 30 parts by weight of a reaction rate modifier. The reaction rate modifier increases the solderability of the solder to the conductor.

### RELATED APPLICATIONS

This patent application is a continuation-in-part of and claims priority to and all advantages of U.S. patent application Ser. No. 10/988,350 which was filed on Nov. 12, 2004.

### BACKGROUND OF THE INVENTION

1. Field of the Invention

The subject invention generally relates to a window pane of a vehicle that includes an electrical connector and an electrical conductor. More specifically, the subject invention relates to an electrical connector that transfers electrical energy to an electrical conductor of the window pane, such as a defogger, defroster, antenna, etc.

2. Description of the Related Art

Electrical connectors are known in the art for use in vehicles. The connectors are soldered to and in electrical communication with an electrical conductor for transferring electrical energy to the conductor. More specifically, the conductors, which generally include sintered silver, are bonded to a substrate that is formed from glass, such as a backlite, sidelite, or windshield of a vehicle. The conductors are commonly visible on window panes of vehicles and typically extend horizontally across the window panes. The conductors are generally defoggers, defrosters, and antennas.

Traditionally, the connectors are soldered to the electrical conductors with a lead-based solder because lead is a deformable metal and minimizes mechanical stress between the connector and the substrate due to difference of thermal expansion of the connector and the substrate resulting from changes in temperature. More specifically, differences in coefficients of thermal expansion between the connectors, which are typically made of a good conductive material such as copper, and the substrates cause the mechanical stress. Such stress may result in cracking or other damage to the substrate, which is typically made of glass. Furthermore, the lead decreases the radical reaction rate between the tin in the solder and the silver in the conductor, allowing for good solderability. However, it is known that lead may be considered an environmental contaminant. As such, there is a motivation in many industries, including the automotive industry, to move away from all uses of lead in vehicles.

Conventional solder materials have been proposed that replace the lead in the solder with additional tin, along with small amounts of silver, copper, indium and bismuth. However, such materials have increased radical reaction rates between the tin-rich solder and the silver conductor, resulting in poor solderability. These conventional materials do not absorb the mechanical stress between the connector and the substrate due to thermal expansion of the connector and the substrate resulting from changes in temperature, which tends to crack or otherwise damage the substrate. Further, many alternative materials for the connector are difficult to solder, making it difficult to sufficiently adhere the connector to the conductor on the substrate. As a result, other techniques would be required in order to sufficiently adhere the alternative materials to the conductor on the substrate.

Although there has been development of various conductors for use in the window panes of vehicles, such developments have little applicability to electrical connector technology. For example, U.S. Pat. No. 6,396,026 discloses a laminated pane for a vehicle including an electrical conductor disposed between two glass panes. The electrical conductor includes a layered structure that may include titanium to provide rigidity to the electrical conductor. The electrical conductor is positioned in an interlayer between the panes. In this position, the electrical conductor is spaced from the glass panes. The titanium-containing conductor in the '026 patent cannot effectively function as a connector that connects a power supply to a conductor that is bonded to one of the glass panes. More specifically, the titanium is disclosed as a core of the conductor, with an outer surface including a more conductive metal such as copper. The titanium core with the outer surface including copper is ineffective for use as an electrical connector due to the presence of the copper because the copper would delaminate from the conductor and/or cause the glass to crack due to mechanical stress between the copper and the glass pane due to thermal expansion of the copper and the glass pane resulting from changes in temperature.

Further, United States Patent Publication No. 2006/0056003 to Tonar et al. provides an electrical device that is typically used on a glass substrate. The electrical device includes a bus connection, i.e., an electrical connector, for supplying electrical power to an electro-optical element. The electrical connector is made from copper alloy or tin-plated copper, both of which are conventional materials that exhibit differences in coefficient of thermal expansion (with glass panes) that are too high. Although Tonar et al. provides that the electrical connector may utilize a metallic clip or strip that may be protected from the environment with metal plating or cladding, the metal plating or cladding performs no role in establishing a bond between the electrical connector and the glass substrate. Even more, many of the materials used for the metal plating or cladding are not of a type that would promote the establishment of a bond between the electrical connector and the connection site, and the difference in coefficients of thermal expansion between the electrical connector and the substrate eliminates any possibility of establishing the bond with a layer of solder.

U.S. Pat. No. 2,644,066 to Glynn provides an electric heater, i.e., an electric conductor, that is disposed on a glass substrate. A metal disc, i.e., an electrical connector, made from a low expansion material is soldered onto the electric heater for supplying electrical power to the electric heater. In terminal areas of the electric heater, a coating of solderable metal is sprayed onto the electric heater because the electric heater is formed from a thin layer of aluminum that is difficult to solder due to its strong surface oxide layer. The electrical connector is connected to the layer of solderable metal through a layer of solder. However, the electrical connector of Glynn is in direct contact with the solder, which is undesirable, especially when the connector is made from materials that are difficult to solder. Further, the solder used in Glynn includes lead, and Glynn does not account for the difficulties that are encountered with traditional solders that do not include lead.

Thus, there remains a need to provide connectors that may be bonded to the conductor through a layer of solder, that may be soldered with solders that do not include lead, that can still reduce the mechanical stress between the connector and the substrate due to thermal expansion of the connector and the substrate resulting from changes in temperature, and that reduce the radical reaction rate to allow for good solderability.

### SUMMARY OF THE INVENTION AND ADVANTAGES

The subject invention provides a window pane. The window pane includes a substrate. The subject invention also provides an electrical device for a window pane, and a vehicle including the window pane. The window pane includes an electrical conductor and an electrical connector. A layer of solderable metal is bonded to the electrical connector. A layer of solder is bonded to the layer of solderable metal and the conductor, with the connector and the conductor in electrical communication through the layer of solderable metal and the layer of solder.

The substrate has a first coefficient of thermal expansion and the connector has a second coefficient of thermal expansion. A difference between the first and second coefficients of thermal expansion is equal to or less than 5×10⁻⁶/° C. for minimizing mechanical stress between the connector and the substrate due to thermal expansion of the connector and the substrate resulting from changes in temperature. As a result, the connector resists delamination from the substrate.

The layer of solderable metal bonded to the connector provides a site to bond to the layer of solder. More specifically, due to the difference between the first and second coefficients of thermal expansion, the connector is typically formed from a material that is difficult to solder, and the layer of solderable metal eliminates any difficulty in bonding the connector to the conductor.

### BRIEF DESCRIPTION OF THE DRAWINGS

Other advantages of the present invention will be readily appreciated as the same becomes better understood by reference to the following detailed description when considered in connection with the accompanying drawings wherein:

FIG. 1 is a perspective view of a vehicle including a rear window pane having an electrical device;

FIG. 2 is a view of the window pane of FIG. 1 with a power supply schematically illustrated;

FIG. 2a is a partial view a portion of the window pane of FIG. 2 including an electrical connector bonded to an electrical conductor;

FIG. 3 is a schematic cross-sectional side view of the window pane taken along line 3-3 in FIG. 2a illustrating the electrical conductor bonded to a ceramic layer, which is bonded to a substrate;

FIG. 4 is a schematic cross-sectional side view of another embodiment of the window pane illustrating the electrical conductor bonded to the substrate absent the ceramic layer;

FIG. 5 is a partial cross-sectional perspective view of yet another embodiment of the window pane including a cladding clad to the electrical connector; and

FIG. 6 is a schematic cross-sectional side view of the window pane taken along line 6-6 of FIG. 5.

### DETAILED DESCRIPTION OF THE PREFERRED EMBODIMENT

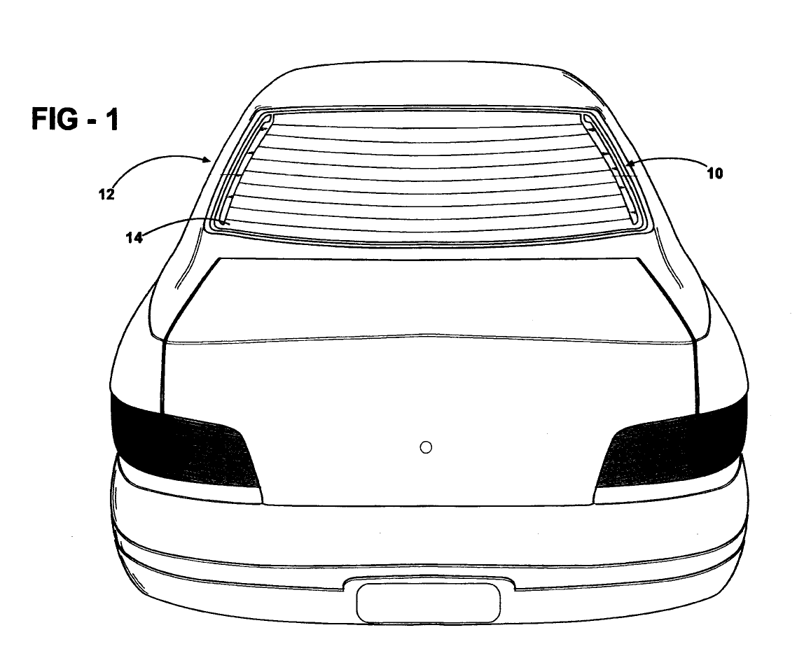

Referring to the Figures, wherein like numerals indicate like or corresponding parts throughout the several views, a window pane is generally shown at 10 on a vehicle 12 in FIG. 1. The window pane 10 includes a substrate 14 that has a first coefficient of thermal expansion. The present invention also provides an electrical device 24 for a window pane 10 having a substrate 14, with the electrical device 24 disposed on the substrate 14. Further, the present invention provides the vehicle 12 including the window pane 10.

Preferably, the substrate 14 is formed from glass; however, the substrate 14 may be formed from other materials such as ceramic. More preferably, the glass is further defined as an automotive glass. In a most preferred embodiment, the automotive glass is further defined as soda-lime-silica glass, which is well known for use in window panes 10 of vehicles 12. However, it is to be appreciated that the glass may be any type of glass composition that is known in the art.

An electrical conductor 16 is applied across a region of the substrate 14. Preferably, the conductor 16 includes silver; however, it is to be appreciated that other conductive metals may also be suitable for the conductor 16. The electrical conductor 16 is visible on the pane 10 and typically includes lines 18 that extend horizontally across the pane 10. The conductor 16 is preferably a defogger, defroster, antenna, or a combination thereof. However, the conductor 16 may serve any function known in the art for such conductors 16.

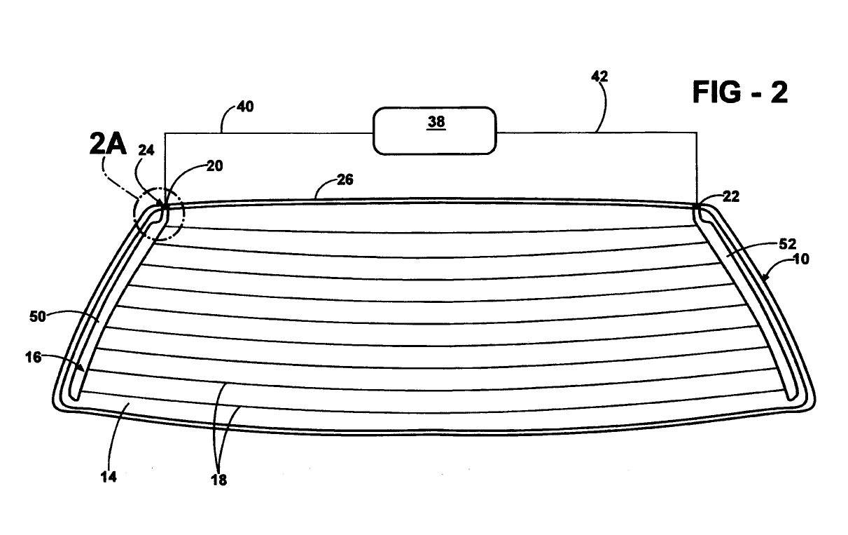

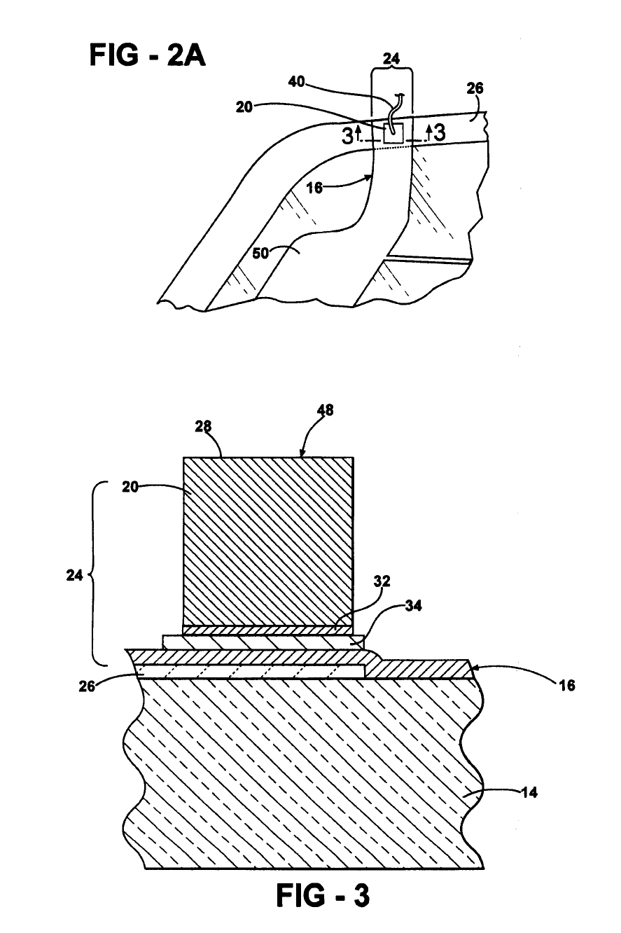

Referring to FIGS. 2 and 2a, the window pane 10 further includes an electrical connector 20. As shown in FIG. 3, a layer of solderable metal 32 is bonded to the connector 20. A layer of solder 34 is bonded to the layer of solderable metal 32 and the conductor 16 with the connector 20 and the conductor 16 in electrical communication through the layer of solderable metal 32 and the layer of solder 34. Together, the conductor 16, the layer of solder 34, the layer of solderable metal 32, and the connector 20 form the electrical device 24.

The electrical connector 20 has a second coefficient of thermal expansion. The connector 20 includes a metal having a low coefficient of thermal expansion (CTE). By “low coefficient of thermal expansion” it is meant that the metal has a sufficiently low CTE to make the difference between the first coefficient of thermal expansion of the substrate 14 and the second coefficient of thermal expansion of the connector 20 less than or equal to 5×10⁻⁶/° C., more typically less than or equal to 4×10⁻⁶/° C., most typically less than or equal to 3×10⁻⁶/° C.. Preferably, the connector 20 includes titanium; however other metals including, but not limited to, iron, molybdenum, tungsten, hafnium, tantalum, chromium, iridium, niobium, vanadium, platinum, and combinations thereof, as well as low CTE iron-nickel alloys, may be suitable for the connector 20 so long as a difference between the first coefficient of thermal expansion of the substrate 14 and the second coefficient of thermal expansion of the connector 20 is less than or equal to 5×10⁻⁶/° C., which will be described in further detail below. The titanium enables the connector 20 to reduce mechanical stress between the connector 20 and the substrate 14 due to thermal expansion of the connector 20 and the substrate 14 resulting from changes in temperature. More specifically, the mechanical stress is caused by differences between the first and second coefficients of expansion. The mechanical stress may cause cracking or other damage to the substrate 14, and may also cause the connector 20 to separate from the substrate 14.

Preferably, the titanium is present in the connector 20 in an amount of at least 50 parts by weight based on 100 parts by weight of the connector 20. In a more preferred embodiment, the titanium is present in the connector 20 in an amount of at least 85 parts by weight, most preferably 99 parts by weight, based on 100 parts by weight of the connector 20. A composition comprising 99 parts by weight of titanium based on 100 parts by weight of the composition is considered commercially pure titanium. In the most preferred embodiment, a remainder of the connector 20 may include iron, oxygen, carbon, nitrogen, and/or hydrogen, each of which may be present in an amount of less than or equal to 0.2 parts by weight based on 100 parts by weight of the connector 20. Other residual elements may also be present in the connector 20 in an amount of less than 0.4 parts by weight based on 100 parts by weight of the connector 20.

In another embodiment, the titanium may be an alloyed titanium that is alloyed with a metal selected from the group of aluminum, tin, copper, molybdenum, cobalt, nickel, zirconium, vanadium, chromium, niobium, tantalum, palladium, ruthenium, and combinations thereof. In this other embodiment, the metal is preferably present in the connector 20 in a total amount of from 0.05 to 50 parts by weight, more preferably from 1 to 10 parts by weight, most preferably from 1 to 5 parts by weight, based on 100 parts by weight of the connector 20.

The titanium, as well as the solder composition that is typically free of lead (to be described in further detail below), is environmentally-friendly, and minimizes harmful effects to the environment to a greater extent than many other materials that are commonly used in connectors and solder compositions. Thus, waste tracking and disposal of excess titanium and solder composition from the manufacturing process and the processing of broken panes 10 is less stringent than for more environmentally harmful materials.

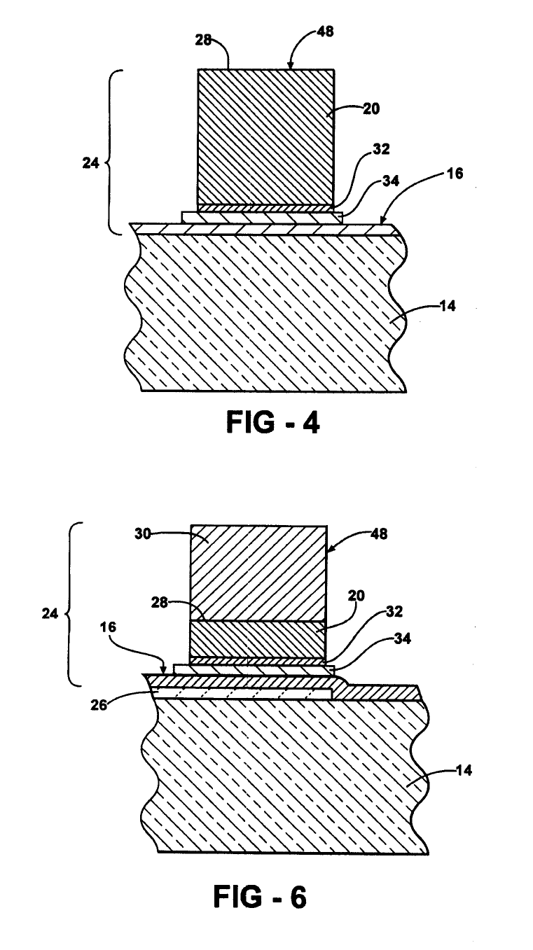

Besides environmental considerations, another advantage of the presence of titanium in the connector 20 is that the titanium has a substantially similar coefficient of thermal expansion to the substrate 14, as briefly discussed above. Referring to FIG. 4, although the connector 20 and the substrate 14 are not directly connected, i.e., the conductor 16, the layer of solderable metal 32, and the layer of solder 34 are disposed between the substrate 14 and the connector 20, the substrate 14, which has the first coefficient of thermal expansion, is rigid and prone to cracking when subjected to mechanical stress resulting from expansion and contraction of the connector 20 due to changes in temperature. Preferably, the conductor 16 has a relatively small thickness from 4×10⁻⁶ to 20×10⁻⁶ m, as compared to the connector 20, which typically has a thickness from 0.2×10⁻³ to 2×10⁻³ m. As a result of the small thickness and silver content of the conductor 16, the conductor 16 is malleable or deformable and deforms when subjected to mechanical stress resulting from expansion and contraction due to changes in temperature. Thus, the conductor 16 absorbs much of the mechanical stress due to changes in temperature. However, the connector 20 also expands and contracts due to the changes in temperature, which also results in mechanical stress that is absorbed by the conductor 16. As a result, substantial differences between the first and second coefficients of thermal expansion result in excessive mechanical stress on the conductor 16 and the substrate 14. The substrate 14 is generally more brittle than both the connector 20 and the conductor 16 and cracks due to the mechanical stress.

As set forth above, a difference between the first and second coefficients of thermal expansion is equal to or less than 5×10⁻⁶/° C.., taken as an average over the temperature range of from 0 to 300° C., which is sufficient to avoid cracking of the substrate 14 up to and including a temperature of 600° C. Preferably, the first coefficient of thermal expansion is from 8 to 9×10⁻⁶/° C. As mentioned above, the substrate is preferably soda-lime-silica glass, which has a coefficient of thermal expansion of from 8.3 to 9×10⁻⁶/° C., most preferably about 8.3×10⁻⁶/° C., also taken as an average over a temperature range of from 0 to 300° C. Preferably, the second coefficient of thermal expansion is from 3 to 13×10⁻⁶/° C., most preferably about 8.8×10⁻⁶/° C., taken as an average over the temperature range of from 0 to 300° C.

As set forth above, the layer of solderable metal 32 is bonded to the connector 20. More specifically, the bond between the layer of solderable metal 32 and the connector 20 is typically a mechanical bond and may be established by any known process including, but not limited to, cladding, sputtering, electroplating, or vacuum plating solderable metal onto the connector 20.

The layer of solderable metal 32 may include any type of solderable metal that is capable of bonding to the connector 20 to establish the bond between the layer of solderable metal 32 and the connector 20, and that further provides a binding site that exhibits excellent adhesion to the layer of solder 34. Preferably, the solderable metal is capable of bonding to titanium. Typically, the solderable metal is selected from the group of copper, zinc, tin, silver, gold, and combinations thereof.

As set forth above, the layer of solder 34 is bonded to the layer of solderable metal 32 and the conductor 16. Typically, the layer of solder 34 is bonded to the layer of solderable metal 32 and the conductor 16 by soldering.

The layer of solder 34 is formed from a solder composition. The solder composition typically includes tin and a reaction rate modifier, and is typically free of lead. The reaction rate modifier in the solder composition improves bonding between the conductor 16 and the layer of solderable metal 32, as opposed to solder compositions that do not include the reaction rate modifier, and also serves the purpose of replacing at least a portion of the tin in the solder composition. Tin generates a compound with silver, such as the silver that may be in the conductor 16, that helps form a strong bond between the layer of solder 34 and the conductor 16. If solder does not include a certain amount of lead, this reaction is too radical and silver at the surface of the conductor 16 dissolves into the solder immediately, resulting in poor solderability and delamination between the layer of solder 34 and the conductor 16. By including the reaction rate modifier in the solder composition instead of lead, the radical reaction may be suppressed and solderability improved in a way that is similar to when lead is included in the solder composition. The reaction rate modifier is typically a low-melting point metal, and may be selected from the group of, but is not limited to, bismuth, indium, zinc, and combinations thereof.

The reaction rate modifier is typically present in the solder composition in an amount of from 30 to 90 parts by weight based on 100 parts by weight of the solder composition. Most preferably, the reaction rate modifier is present in the solder composition in an amount of from 40 to 60 parts by weight, based on 100 parts by weight of the solder composition. The tin is typically included in the solder composition in an amount of from 10 to 70 parts by weight, most preferably from 25 to 50 parts by weight, based on 100 parts by weight of the solder composition. In addition to the tin and reaction rate modifier, the solder composition may also include other metals including, but not limited to, silver, copper, and combinations thereof for providing durability to the solder composition. When present, the silver may be included in an amount of equal to or less than 5 parts by weight based on 100 parts by weight of the solder composition. The copper may be included in an amount of equal to or less than 5 parts by weight based on 100 parts by weight of the solder composition, independent of the amount of silver included in the solder composition.

The layer of solderable metal 32 and the layer of solder 34 typically have a combined thickness that is sufficiently small to eliminate any effect of differences in coefficient of thermal expansion between the layer of solderable metal 32, the layer of solder 34, the connector 20, and the substrate 14. More specifically, the layer of solderable metal 32 and the layer of solder 34 typically have a combined thickness of less than or equal to 3.0×10⁻⁴ m, based on experimental results, which is sufficiently small to make the coefficient of thermal expansion of both the layer of solderable metal 32 and the layer of solder 34 immaterial, especially when the connector 20 has a thickness as great as 2×10⁻³ m. Due to the combined thickness of the layer of solderable metal 32 and the layer of solder 34 of less than or equal to 3.0×10⁻⁴ m, and the position of the layer of solderable metal 32 and the layer of solder 34 between two relatively stiff materials, i.e., the connector 20 and the substrate 14, the layer of solderable metal 32 and the layer of solder 34 will deform during heating and cooling instead of transmitting thermal expansion mismatch stress to the substrate 14.

It is to be appreciated that the electrical device 24 of the present invention includes the connector 20, the layer of solderable metal 32, the layer of solder 34, and the conductor 16, to the exclusion of the substrate 14. More specifically, the electrical device 24 exists separate from the substrate 14, and the electrical device 24 need not necessarily be incorporated in conjunction with the window pane 10.

Besides silver, the conductor 16 may also include other materials such as glass frit and flow modifiers. The conductor 16 is applied to the substrate 14 as a paste, which is subsequently fired onto the substrate 14 through a sintering process. More specifically, after the paste is applied to the substrate 14, the substrate 14 is subjected to a low temperature bake at about 200° C., which causes the flow modifiers to flash out of the paste. The substrate 14 is then subjected to sintering at about 650° C., which fires the paste onto the substrate 14 to form the conductor 16. The sintering process also prevents mechanical stress from developing between the conductor 16 and the substrate 14.

When the conductor 16 is a defroster or defogger, the conductor 16 may further include vertical strips 50, 52, in addition to the lines 18, disposed on opposite ends of the lines 18. The strips 50, 52 electrically connect the lines 18. The strips 50, 52, in combination with the lines 18, form a parallel circuit.

Referring to FIGS. 2 and 3, the pane 10 may include a ceramic layer 26 disposed adjacent to a periphery of the pane 10. The ceramic layer 26 protects an adhesive on the substrate 14 from UV degradation. As known in the art, such adhesive is typically utilized to adhere the pane 10 to a body of the vehicle 12. Thus, as shown in FIG. 3, the ceramic layer 26 may be disposed between the substrate 14 and the conductor 16. The ceramic layer 26 is generally black in color and has a negligible effect on the thermal expansion dynamics between the substrate 14, the conductor 16, and the connector 20. Thus, in terms of thermal expansion dynamics, there is no significant difference between the configuration as shown in FIG. 3, wherein the connector 20 is bonded to the conductor 16 on top of the ceramic layer 26, and the configuration as shown in FIG. 4, wherein the connector 20 is bonded to the conductor 16 on top of the substrate 14.

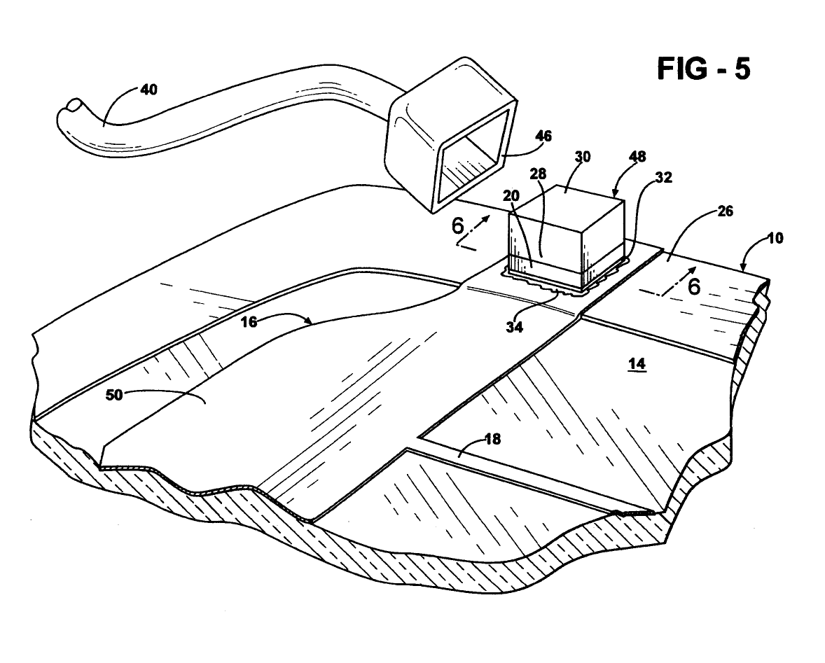

In one embodiment, shown in FIGS. 5 and 6, the connector 20 has an outer surface area 28 and a cladding 30 clad to the outer surface area 28. It is to be appreciated that “cladding” refers to a layer of metal bonded to a metal substrate, in this case the connector 20, and is not in any way limited to a method by which the cladding 30 is formed on the connector 20. Preferably, the cladding 30 includes a metal selected from the group of copper, silver, aluminum, gold, and combinations thereof. The cladding 30 is more electrically conductive than the titanium to improve flow of electricity through the connector 20. The cladding 30 is spaced from the conductor 16 such that the cladding 30 is mechanically insulated from the conductor 16 to avoid undue mechanical stress on the substrate 14 as discussed above, since the cladding 30 has a substantially different coefficient of thermal expansion from the substrate 14.

Preferably, the cladding 30 and the connector 20 are present relative to one another in a volumetric ratio of from 0.01:1 to 4:1 such that the connector 20 includes enough titanium to sufficiently minimize the mechanical stress caused by expansion and contraction of the cladding 30 due to the changes in temperature.

In another embodiment, the connector 20 may comprise the alloyed titanium that has 50 parts by weight or less of copper based on 100 parts by weight of the connector 20, with the balance comprising titanium, to eliminate the need for the cladding 30.

The connector 20 transfers electrical energy to the conductor 16. Typically, the connector 20 is connected to the conductor 16, through the layer of solderable metal 32 and the layer of solder 34, adjacent the periphery of the pane 10 on one side of the pane 10. Preferably, a second connector 22 is bonded to and in electrical communication with the conductor 16, also through a layer of solderable metal 32 and a layer of solder 34, on an opposite side of the pane 10 from the connector 20. However, it is to be appreciated that the second connector 22 is optional. The second connector 22 may transfer electrical energy away from the conductor 16. In one embodiment, as shown schematically in FIG. 2, the vehicle 12 includes the power supply 38 for providing the electrical energy. The power supply 38 may be a battery, alternator, etc. Preferably, both the connector 20 and the second connector 22 are operatively connected to and in electrical communication with the power supply 38. The connector 20 transfers electrical energy from the power supply 38 to the conductor 16, through the layer of solderable metal 32 and the layer of solder 34, and the second connector 22 transfers electrical energy from the conductor 16 to the power supply 38. More specifically, a lead wire 40 is operatively connected to and extends from the power supply 38 adjacent to the substrate 14. The lead wire 40 is also operatively connected to the connector 20. Another wire 42 extends from the power supply 38 to the second connector 22 and is operatively connected to the second connector 22 to complete an electrical circuit. The lead wire 40 and the wire 42 preferably include copper.

The operative connection between the lead wire 40 and the connector 20 may be formed through welding, a mechanical connection, etc. In one embodiment, a female member 46 extends from one of the connector 20 and the lead wire 40. A male member 48 extends from the other of the connector 20 and the lead wire 40 for operatively connecting to the female member 46. That is, as shown in FIG. 5, the female member 46 can extend from the lead wire 40 when the male member 48 extends from the connector 20, and vice versa. The operative connection between the second connector 22 and the second lead wire 42 may be the same as the operative connection between the connector 20 and the lead wire 40. In a most preferred embodiment, shown in FIG. 5, the lead wire 40 includes the female member 46 and the connector 20 includes the male member 48. The female member 46 engages the male member 48 through compression to prevent separation between the lead wire 40 and the connector 20. However, it is to be appreciated that the members 46, 48 may be connected through welding or other processes.

### EXAMPLES

Test plaques were made including the glass substrate 14, the electrical conductor 16, the electrical connector 20 including the layer of solderable metal 32, and the layer of solder 34. Half of the test plaques include glass substrates 14 with a ceramic layer 26, and the electrical conductor 16 was bonded to the glass substrate 14 over the ceramic layer 26. However, the results were the same for both configurations. The electrical conductor 16 was formed from silver paste for all of the plaques, and the silver paste was fired onto the substrate 14 to form the electrical conductor 16. The layer of solderable metal 32 was formed on the connector 20 by sputtering. The connector 20 was soldered to the conductor 16 through the layer of solder 34. The electrical connector 20, the layer of solderable metal 32, and the layer of solder 34 were formed from metals as indicated in Table 1. The glass substrate 14 was formed from soda-lime-silica

Further, the connectors soldered to the plaques were subjected to a pull test at least 24 hours after soldering. Referring to Table 1, the type and amount of metal used for the connector 20, the layer of solderable metal 32, and the layer of solder 34 are shown for each of the plaques, with amounts in parts by weight based on 100 parts by weight of the connector 20, the layer of solderable metal 32, or the layer of solder 34, respectively, along with an indication of whether or not the plaque exhibits sufficient performance when subjected to changes in temperature. Furthermore, the properties of the soda-lime-silica glass are also included in the Table 1.

TABLE 1

| | Material | Ex. A | Ex. B |
|---|---|---|---|
| Electrical | Titanium | 100.00 | 100.00 |
| Connector | Avg. CTE, ×10⁻⁶/° C. over range | 8.80 | 8.80 |
| | of 0-100° C. | | |
| | Difference between CTE of Connector | 0.5 | 0.5 |
| | and Glass Substrate, ×10⁻⁶/° C. | | |
| | over a range of 0-100° C. | | |
| | Thickness of Electrical Connector, m | 8.0 × 10⁻⁴ | 8.0 × 10⁻⁴ |
| Layer of | Copper | 100.00 | 100.00 |
| Solderable | Thickness of Layer of Solderable | 5.0 × 10⁻⁶ | 5.0 × 10⁻⁶ |
| metal | Metal, m | | |
| Layer of solder | Tin | 48 | 30 |
| | Bismuth | 46 | 64 |
| | Silver | 2 | 2 |
| | Copper | 4 | 4 |
| | Thickness of Layer of Solder, m | 50-200 × 10⁻⁶ | 50-200 × 10⁻⁶ |
| | Combined Thickness of Layer of | 55-205 × 10⁻⁶ | 55-205 × 10⁻⁶ |
| | Solderable Metal and Layer of Solder, m | | |
| Glass Substrate | Avg CTE, ×10⁻⁶/° C. over | 8.3 | 8.3 |
| (Soda-Lime- | range of 0-302° C. | | |
| Silica) | Results of Pull Test | Good Pull | Good Pull |
| | | Strength | Strength |

### COMPARATIVE EXAMPLES

Comparative Examples of plaques are made for comparison to the plaques made in accordance with the present invention. More specifically, plaques for Comparative Examples A thru D were made the same as set forth above in the Examples, except for the amount of reaction rate modifier used and the thickness of the layer of solderable metal. In Comparative Example B, no layer of solderable metal is present. Referring to Table 2, the type and amount of metal used for the connector and the layer of solder are shown for each of the plaques, with amounts in parts by weight based on 100 parts by weight of the connector or the layer of solder, respectively, along with an indication of whether or not the plaque exhibits sufficient performance when subjected to changes in temperature. Furthermore, the properties of the soda-lime-silica glass are also included in the Table 2.

TABLE 2

| | Material | Comp. Ex. A | Comp. Ex. B |
|---|---|---|---|
| Electrical | Titanium | 100.00 | 100.00 |
| Connector | Avg. CTE, ×10⁻⁶/° C. over range of 0-100° C. | 8.80 | 8.80 |
| | Difference between CTE of Connector | 0.5 | 0.5 |
| | and Glass Substrate, ×10⁻⁶/° C. over a | | |
| | range of 0-100° C. | | |
| | Thickness of Electrical Connector, m | 8.0 × 10⁻⁴ | 8.0 × 10⁻⁴ |
| Layer of | | | None |
| Solderable metal | | | |
| | Copper | 100.00 | 0.00 |
| | Thickness of Layer of Solderable | 500 × 10⁻⁶ | 0.00 |
| | Metal, m | | |
| Layer of solder | Tin | 48 | 48 |
| | Bismuth | 46 | 46 |
| | Silver | 2 | 2 |
| | Copper | 4 | 4 |
| | Thickness of Layer of Solder, m | 50-200 × 10⁻⁶ | 50-200 × 10⁻⁶ |
| | Combined Thickness of Layer of | 550-700 × 10⁻⁶ | 50-200 × 10⁻⁶ |
| | solderable metal and Layer of solder, m | | |
| Glass Substrate | Avg CTE, ×10⁻⁶/° C. over range of 0-302° C. | 8.3 | 8.3 |
| (Soda-Lime-Silica) | Results of Elevated Temperature Test | Substrate | No |
| | | cracks, | adhesion |
| | | Poor pull | |
| | | strength | |
| | Material | Comp Ex. C | Comp Ex. D |
| Electrical | Titanium | 100.00 | 100.00 |
| Connector | Avg. CTE, ×10⁻⁶/° C. over range of 0-100° C. | 8.80 | 8.80 |
| | Difference between CTE of Connector | 0.5 | 0.5 |
| | and Glass Substrate, ×10⁻⁶/° C. over a | | |
| | range of 0-100° C. | | |
| | Thickness of Electrical Connector, m | 8.0 × 10⁻⁴ | 8.0 × 10⁻⁴ |
| Layer of | Copper | 100.00 | 100.00 |
| Solderable metal | Thickness of Layer of Solderable | 5.0 × 10⁻⁶ | 5.0 × 10⁻⁶ |
| | Metal, m | | |
| Layer of solder | Tin | 90 | 48 |
| | Bismuth | 7.5 | 46 |
| | Silver | 2.0 | 2 |
| | Copper | 0.5 | 4 |
| | Thickness of Layer of Solder, m | 50-200 × 10⁻⁶ | 400-500 × 10⁻⁶ |
| | Combined Thickness of Layer of | 55-205 × 10⁻⁶ | 405-505 × 10⁻⁶ |
| | solderable metal and Layer of solder, m | | |
| Glass Substrate | Avg CTE, ×10⁻⁶/° C. over range of 0-302° C. | 8.3 | 8.3 |
| (Soda-Lime-Silica) | Results of Elevated Temperature Test | Poor | Substrate |
| | | solderability, | cracks, |
| | | Poor pull | Poor pull |
| | | strength | strength |

Obviously, many modifications and variations of the present invention are possible in light of the above teachings. It is, therefore, to be understood that within the scope of the appended claims, the invention may be practiced otherwise than as specifically described.

What is claimed is:

1. A window pane comprising:
a substrate formed from glass and having a first coefficient of thermal expansion;
an electrical conductor applied across a region of said substrate;
an electrical connector having a second coefficient of thermal expansion with a difference between said first and second coefficients of thermal expansion equal to or less than 5×10⁻⁶/° C.;
a layer of solderable metal bonded to said connector; and
a layer of solder bonded to said layer of solderable metal and said conductor with said connector and said conductor in electrical communication through said layer of solderable metal and said layer of solder.

2. A window pane as set forth in claim 1 wherein said layer of solderable metal and said layer of solder have a combined thickness of less than or equal to 3.0×10⁻⁴ m.

3. A window pane as set forth in claim 1 wherein said bond between said layer of solder and said layer of solderable metal and between said layer of solder and said conductor is further defined as a metallic bond.

4. A window pane as set forth in claim 1 wherein said layer of solderable metal comprises a solderable metal selected from the group of copper, zinc, tin, silver, gold, and combinations thereof.

5. A window pane as set forth in claim 1 wherein said layer of solder is formed from a solder composition.

6. A window pane as set forth in claim 5 wherein said solder composition comprises a reaction rate modifier.

7. A window pane as set forth in claim 6 wherein said reaction rate modifier is selected from the group of bismuth, indium, zinc, and combinations thereof.

8. A window pane as set forth in claim 6 wherein said reaction rate modifier is present in said solder composition in an amount of from about 30 to about 90 parts by weight based on 100 parts by weight of said solder composition.

9. A window pane as set forth in claim 6 wherein said solder composition further comprises tin.

10. A window pane as set forth in claim 9 wherein said tin is present in said solder composition in an amount of from about 10 to about 70 parts by weight based on 100 parts by weight of said solder composition.

11. A window pane as set forth in claim 5 wherein said solder composition is free of lead.

12. A window pane as set forth in claim 1 wherein said second coefficient of thermal expansion is from 3 to 13×10⁻⁶/° C..

13. A window pane as set forth in claim 1 wherein said first coefficient of thermal expansion is from 8 to 9×10⁻⁶/° C..

14. A window pane as set forth in claim 1 wherein said connector comprises at least one of titanium, molybdenum, tungsten, hafnium, tantalum, chromium, iridium, niobium, platinum, and vanadium.

15. A window pane as set forth in claim 1 wherein said connector comprises titanium.

16. A window pane as set forth in claim 15 wherein said titanium is present in said connector in an amount of at least 50 parts by weight based on 100 parts by weight of said connector.

17. A window pane as set forth in claim 16 wherein said titanium is present in said connector in an amount of at least 85 parts by weight based on 100 parts by weight of said connector.

18. A window pane as set forth in claim 15 wherein said titanium is alloyed with a metal selected from the group of aluminum, tin, copper, molybdenum, cobalt, nickel, zirconium, vanadium, chromium, niobium, tantalum, palladium, ruthenium, and combinations thereof.

19. A window pane as set forth in claim 18 wherein said metal is present in an amount of from 0.05 to 50 parts by weight based on 100 parts by weight of said connector.

20. A window pane as set forth in claim 1 wherein said connector comprises an iron-nickel alloy.

21. A window pane as set forth in claim 1 wherein said connector has an outer surface area and a cladding clad to said outer surface area and spaced from said conductor such that said cladding is mechanically insulated from said conductor.

22. A window pane as set forth in claim 21 wherein said cladding comprises a metal selected from the group of copper, silver, aluminum, gold, and combinations thereof.

23. A window pane as set forth in claim 1 wherein said conductor comprises silver.

24. A window pane as set forth in claim 1 further comprising a ceramic layer disposed between said substrate and said conductor.

25. A window pane as set forth in claim 1 wherein said glass is further defined as automotive glass.

26. A window pane as set forth in claim 25 wherein said glass is further defined as soda-lime-silica glass.

27. A window pane as set forth in claim 1 wherein said conductor is selected from the group of defoggers, defrosters, antennas, and combinations thereof.
